(19) United States
(12) Patent Application Publication
(10) Pub. No.: US 2013/0069130 A1
(43) Pub. Date: Mar. 21, 2013

(54) SOLID STATE IMAGING DEVICE

(71) Applicant: Kazunori Kakehi, Oita-shi (JP)

(72) Inventor: Kazunori Kakehi, Oita-shi (JP)

(21) Appl. No.: 13/426,945

(22) Filed: Mar. 22, 2012

(30) Foreign Application Priority Data
Sep. 20, 2011 (JP) 2011-205061

(51) Int. Cl. H01L 31/113; H01L 31/0232

(52) U.S. Cl. 257/292; 257/432; 257/E31.127; 257/E31.083

(57) ABSTRACT

According to one embodiment, a solid state imaging device includes a semiconductor substrate having a first surface on a light incident side and a second surface on a side opposite to the light incident side, a photodiode in the semiconductor substrate, a functional layer which covers the entire photodiode on the side of the first surface of the semiconductor substrate, and has a function of transmitting the light traveling from an exterior to an interior of the semiconductor substrate, and reflecting the light traveling from the interior to the exterior of the semiconductor substrate, and a reflecting layer which covers the entire second surface of the semiconductor substrate, and has a function of reflecting the light traveling from the interior to the exterior of the semiconductor substrate.

### CROSS-REFERENCE TO RELATED APPLICATIONS

This application is based upon and claims the benefit of priority from prior Japanese Patent Application No. 2011-205061, filed Sep. 20, 2011, the entire contents of which are incorporated herein by reference.

### FIELD

Embodiments described herein relate generally to a solid state imaging device.

### BACKGROUND

In a solid state imaging device such as a CMOS image sensor or a CCD (Charge Coupled Device), a photodiode of a pixel section has a physical limit in miniaturization in the vertical direction (light incident direction) perpendicular to the surface of a substrate. This physical limit depends on the light absorbance of a substrate (for example, silicon) in which a photodiode is formed.

Assuming, for example, that the substrate thickness required to absorb 50% of red light (wavelength: about 700 nm) that is most poorly absorbed among the three primary colors of light is the physical limit in vertical miniaturization, the physical limit in vertical miniaturization is about 3 μm when the substrate is silicon.

In contrast to this, the physical limit in miniaturization in the horizontal direction (a direction parallel to the surface of a substrate) of a photodiode depends on, for example, the processing accuracy of photolithography. In recent years, with an improvement in processing accuracy of photolithography, the physical limit in horizontal miniaturization of a photodiode has improved to the order of nanometers. Hence, the number of pixels has increased upon a reduction in horizontal size of a photodiode.

However, when only the horizontal size of a photodiode is reduced while its vertical size remains the same, an aspect ratio R (R=vertical size/horizontal size) of a layer which extends from the front side to the back side of the substrate increases, thus making it more difficult to form this layer. An element isolation layer, a conductive layer such as TSV (Through Silicon Via), and an alignment mark, for example, are layers which extend from the front side to the back side of the substrate.

### BRIEF DESCRIPTION OF THE DRAWINGS

FIG. 1 is a view showing a first basic structure;

FIG. 2 is a view showing a second basic structure;

FIG. 3 is a view showing a CMOS image sensor;

FIG. 4 is a circuit diagram showing a readout circuit of the CMOS image sensor;

FIG. 5 is a view showing a front side illumination type image sensor;

FIG. 6 is a view showing a back side illumination type image sensor; and

FIGS. 7 to 10 are views showing a method of manufacturing the image sensor shown in FIG. 6.

### DETAILED DESCRIPTION

In general, according to one embodiment, a solid state imaging device includes a semiconductor substrate having a first surface on a light incident side and a second surface on a side opposite to the light incident side; a photodiode in the semiconductor substrate; a functional layer which covers the entire photodiode on the side of the first surface of the semiconductor substrate, and has a function of transmitting the light traveling from an exterior to an interior of the semiconductor substrate, and reflecting the light traveling from the interior to the exterior of the semiconductor substrate; and a reflecting layer which covers the entire second surface of the semiconductor substrate, and has a function of reflecting the light traveling from the interior to the exterior of the semiconductor substrate.

Embodiments will be described below with reference to the accompanying drawings.

### 1. BASIC STRUCTURE

To miniaturize a solid state imaging device in the vertical direction (light incident direction) perpendicular to the surface of a substrate, first, it is effective to form the substrate using a material which can easily absorb incident light; and second, it is effective to reflect incident light to trap it in the substrate. The latter technique of trapping incident light in the substrate will be described in the following embodiment.

To trap incident light in the substrate, a technique of forming reflecting layers on both the front and back sides of the substrate is especially available. In this specification, the reflecting layer means a layer which reflects almost 100% of light without transmitting it.

When, for example, light strikes the substrate from its front side, an opening which guides the light into the substrate is formed in the reflecting layer on the front side of the substrate while the entire back side of the substrate is covered with the reflecting layer. However, when light strikes the substrate from its back side, an opening which guides the light into the substrate is formed in the reflecting layer on the back side of the substrate while the entire front side of the substrate is covered with the reflecting layer.

Unfortunately, in this technique, light coming from the opening in the reflecting layer on one side of the substrate is reflected by the reflecting layer on the other side of the substrate, and leaves the substrate to the outside again from the aperture in the reflecting layer on one side of the substrate. Therefore, the surface shape of the reflecting layer on the other side of the substrate must be modified to form a structure in which light reflected on the other side of the substrate is reflected again on one side of the substrate.

To meet this requirement, it is necessary to develop a process of controlling the surface shape of the reflecting layer with high accuracy. However, the development of such a process requires an enormous cost. In addition, even if such a process is developed, it is difficult to control the angle of reflection of light with high accuracy, so the throughput and the manufacturing yield, for example, are expected to degrade.

Hence, the following embodiment proposes a technique which achieves vertical miniaturization of a photodiode by reliably trapping incident light in the substrate even without controlling the surface shape of the reflecting layer.

Although a feature of the following embodiment lies in that incident light is reliably trapped in the substrate even without controlling the surface shape of the reflecting layer, the technique according to this embodiment and a technique of controlling the surface shape of the reflecting layer can be combined, as a matter of course.

A basic structure will be described first.

The following embodiment merely provides an example of the conductivity type of a semiconductor substrate or each layer in this substrate. A solid state imaging device having conductivity types that are all opposite to those in a solid state imaging device to be described hereinafter, for example, can also be used.

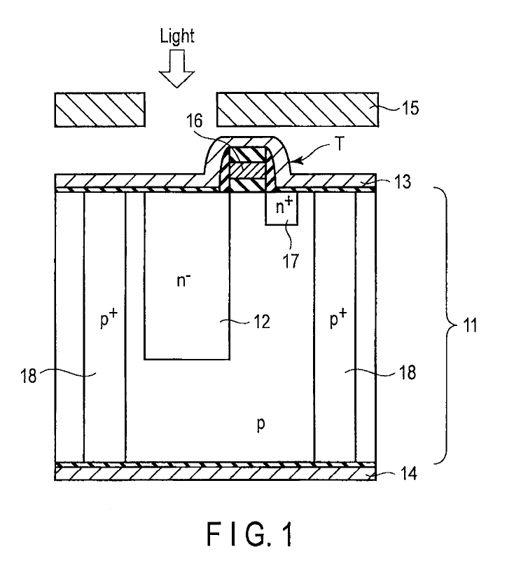

FIG. 1 shows a first basic structure.

This basic structure relates to an FSI type (Front Side Illumination type) solid state imaging device.

P-type semiconductor substrate 11 has a first surface (front surface) on the light incident side and a second surface (back surface) opposite to this light incident side. Photodiode 12 is an n⁻-type diffusion layer in p-type semiconductor substrate 11. Note that p-type semiconductor substrate 11 may be replaced with a p-type semiconductor layer epitaxially grown on an n-type semiconductor substrate, or a p-type impurity region formed in an n-type semiconductor substrate.

Functional layer 13 covers entire photodiode 12 on the side of the first surface of p-type semiconductor substrate 11. Although functional layer 13 covers the entire first surface in the embodiment, it need only cover the portion directly above photodiode 12. Nevertheless, from the viewpoint of the simplicity of a manufacturing process (to be described later), functional layer 13 desirably covers the entire first surface.

Functional layer 13 has a function of transmitting light traveling from the exterior to the interior of p-type semiconductor substrate 11, and reflecting light traveling from the interior to the exterior of p-type semiconductor substrate 11. An example of functional layer 13 is a translucent layer having a light transmittance X (%) and a light reflectance Y (%), that satisfy X+Y≦100.

Reflecting layer 14 covers the entire second surface of p-type semiconductor substrate 11, and has a function of reflecting light traveling from the interior to the exterior of p-type semiconductor substrate 11.

Note that light enters only photodiode 12 via an opening formed in light-shielding layer 15 on the side of the first surface. Read transistor T which uses an FET (Field Effect Transistor) transfers charges (signals) generated by photodiode 12 to floating diffusion (n⁺-type diffusion layer) 17 under the control of the voltage applied to gate 16.

Element isolation layer 18 is a pt-type diffusion layer in p-type semiconductor substrate 11. Element isolation layer 18 prevents charges generated in one pixel cell including photodiode 12 from leaking into other pixel cells adjacent to the pixel cell including photodiode 12.

Note that element isolation layer 18 can also be replaced with an insulating layer such as an oxide layer which uses DTI (Deep Trench Isolation).

With such a structure, the first surface on the light incident side is covered with functional layer 13 such as a translucent layer. Since functional layer 13 transmits light traveling from the exterior to the interior of p-type semiconductor substrate 11, there is no need to form an opening in it. In addition, since functional layer 13 reflects light traveling from the interior to the exterior of p-type semiconductor substrate 11, there is no need, either, to modify the surface shape of reflecting layer 14 formed on the second surface.

Accordingly, with the first basic structure, incident light can be reliably trapped in p-type semiconductor substrate 11, thereby achieving vertical miniaturization of photodiode 12.

Also, since it is necessary neither to form an opening in functional layer 13 on the first surface nor to control the surface shape of reflecting layer 14 on the second surface, the manufacturing process can be simplified, the manufacturing cost can be lowered, and the production throughput and the manufacturing yield can be improved, compared to the conventional structure having reflecting layers formed on both the first and second surfaces.

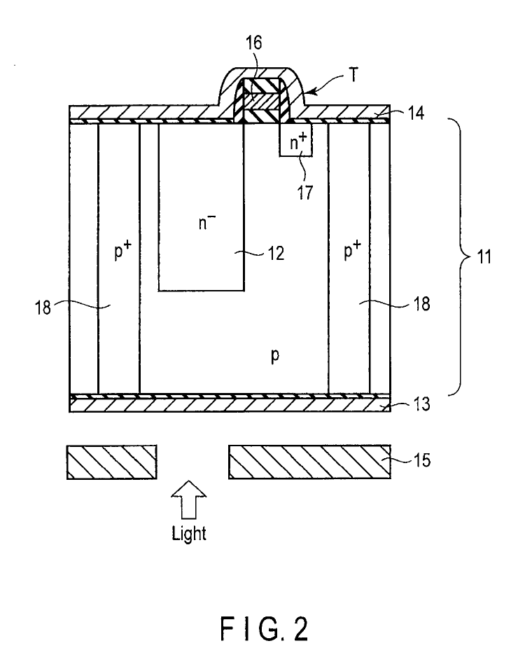

FIG. 2 shows a second basic structure.

This basic structure relates to a BSI type (Back Side Illumination type) solid state imaging device.

P-type semiconductor substrate 11 has a first surface (front surface) on the light incident side and a second surface (back surface) opposite to this light incident side. Photodiode 12 is an n⁻-type diffusion layer in p-type semiconductor substrate 11. Note that p-type semiconductor substrate 11 may be replaced with a p-type semiconductor layer epitaxially grown on an n-type semiconductor substrate, or a p-type impurity region formed in an n-type semiconductor substrate.

Functional layer 13 covers entire photodiode 12 on the side of the first surface of p-type semiconductor substrate 11. Although functional layer 13 covers the entire first surface in the embodiment, it need only cover the portion directly above photodiode 12. Nevertheless, from the viewpoint of the simplicity of the manufacturing process, functional layer 13 desirably covers the entire first surface, as in the first basic structure.

Functional layer 13 has a function of transmitting light traveling from the exterior to the interior of p-type semiconductor substrate 11, and reflecting light traveling from the interior to the exterior of p-type semiconductor substrate 11. An example of functional layer 13 is a translucent layer having a light transmittance X (%) and a light reflectance Y (%), that satisfy X+Y≦100.

Reflecting layer 14 covers the entire second surface of p-type semiconductor substrate 11, and has a function of reflecting light traveling from the interior to the exterior of p-type semiconductor substrate 11.

Note that light enters only photodiode 12 via an opening formed in light-shielding layer 15 on the side of the first surface. Read transistor T which uses an FET (Field Effect Transistor) transfers charges (signals) generated by photodiode 12 to floating diffusion (n⁺-type diffusion layer) 17 under the control of the voltage applied to gate 16.

Element isolation layer 18 is a p⁺-type diffusion layer in p-type semiconductor substrate 11. Element isolation layer 18 prevents charges generated in one pixel cell including photodiode 12 from leaking into other pixel cells adjacent to the pixel cell including photodiode 12.

Note that element isolation layer 18 can also be replaced with an insulating layer such as an oxide layer (DTI).

With such a structure, the first surface on the light incident side is covered with functional layer 13 such as a translucent layer. Since functional layer 13 transmits light traveling from the exterior to the interior of p-type semiconductor substrate 11, there is no need to form an opening in it. In addition, since functional layer 13 reflects light traveling from the interior to the exterior of p-type semiconductor substrate 11, there is no need, either, to modify the surface shape of reflecting layer 14 formed on the second surface.

Accordingly, with the second basic structure, incident light can be reliably trapped in p-type semiconductor substrate 11, thereby achieving vertical miniaturization of photodiode 12.

Also, since it is necessary neither to form an opening in functional layer 13 on the first surface nor to control the surface shape of reflecting layer 14 on the second surface, the manufacturing process can be simplified, the manufacturing cost can be lowered, and the production throughput and the manufacturing yield can be improved, compared to the conventional structure having reflecting layers formed on both the first and second surfaces.

Note that in each of the first and second basic structures, p-type semiconductor substrate 11 includes compound semiconductor substrates such as a GaAs substrate, in addition to a silicon substrate.

### 2. EXAMPLE

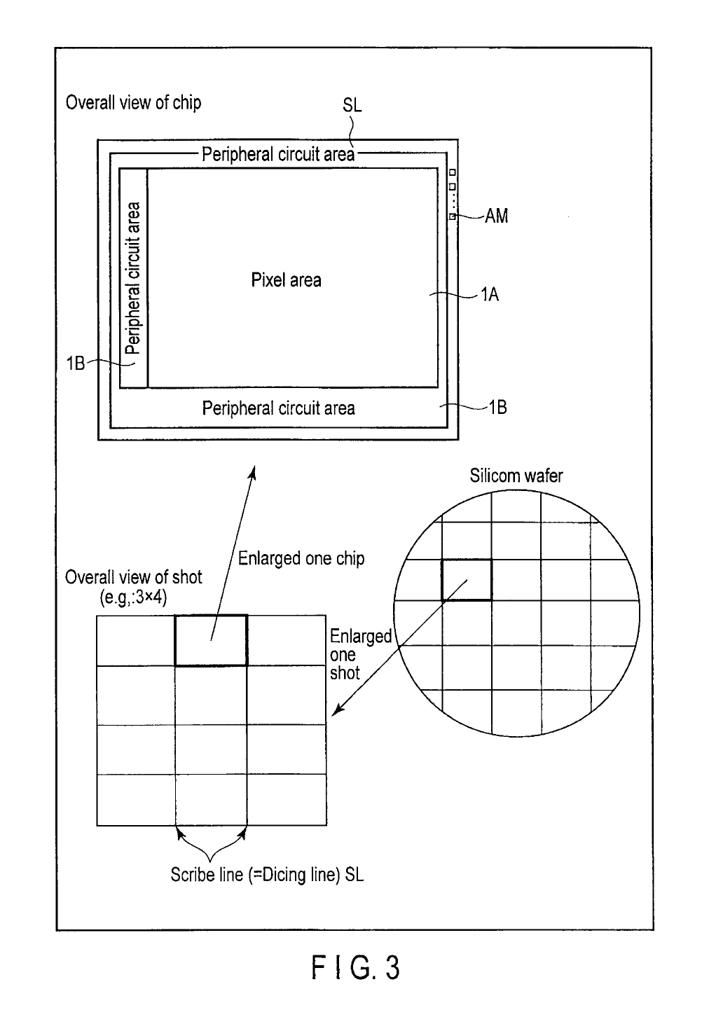

FIG. 3 shows a CMOS image sensor (a wafer, one shot, and a chip).

When, for example, several hundred chips are manufactured from one wafer, shots are formed on this wafer and exposed to light. In this Example, 3×4 chips are transferred onto a wafer for each shot. One shot includes chips and scribe lines SL between these chips. After a wafer process and before a packaging process, the wafer is cut along scribe lines SL to manufacture several hundred chips.

As shown in an overview of chips, the CMOS image sensor has pixel area 1A in most part within one chip, and peripheral circuit area 1B is formed around pixel area 1A. Also, when a back side illumination type image sensor is used as the CMOS image sensor, the area occupied by pixel area 1A within one chip can be set relatively large. Alignment mark AM used for alignment in a wafer process falls within, for example, scribe lines SL.

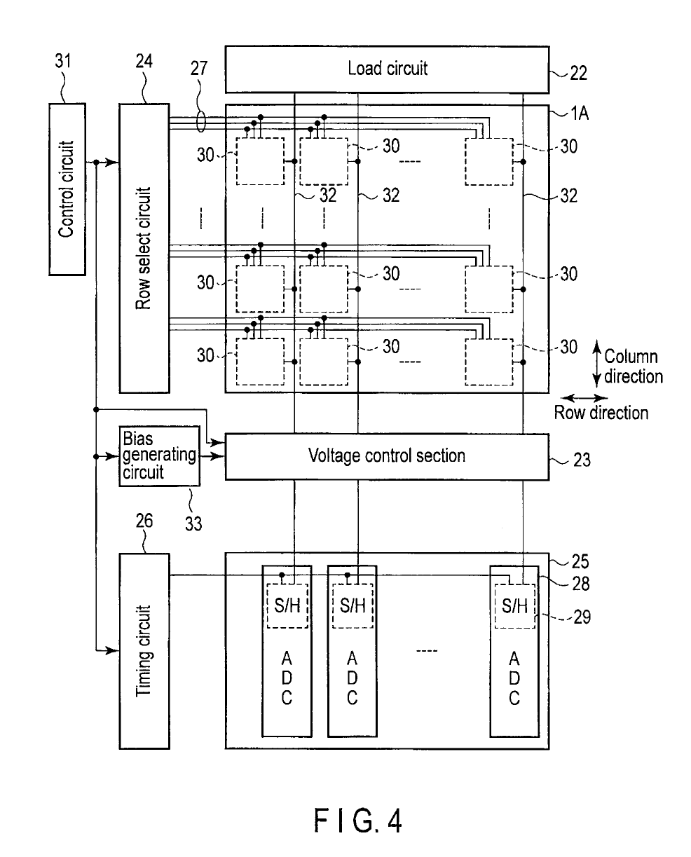

FIG. 4 is a circuit diagram showing the CMOS image sensor.

Pixel area 1A includes arrayed pixel cells 30. An area other than pixel area 1A is a peripheral circuit area. The peripheral circuit area includes load circuit 22 for readout, voltage control section 23 which controls the voltages of output signal lines 32, row select circuit 24, A/D (Analog-Digital) conversion block 25, timing circuit 26, and bias generating circuit 33.

Control circuit 31 controls the operations of voltage control section 23, row select circuit 24, timing circuit 26, and bias generating circuit 33.

Row select circuit 24 uses control signal line 27 extending in the row direction to select one row (one horizontal line) of the pixel cell array from which pixel signals are to be read, and control readout of pixel signals from pixel cells 30 in one horizontal line.

When a 4-Tr type CMOS image sensor in which each pixel includes four transistors for readout, for example, is used, control signal line 27 in one horizontal line includes three signals lines (a row select line, a reset control line, and a read control line).

One vertical signal line (output signal line) 32 is provided to each column (each vertical line) of the pixel cell array. Voltage control section 23 controls the voltages of output signal lines 32.

A/D conversion block 25 comprises, for example, A/D converters 28 each including sample-hold (S/H) circuit 29.

Sample-hold circuit 29 samples and holds the voltage (reset voltage) of output signal line 32 when the reset voltage of the floating diffusion is boosted. The charges of the photodiode are transferred to the floating diffusion to read pixel signals.

After pixel signals are read, the voltage of output signal line 32 changes with a change in voltage of the floating diffusion, and serves as a signal voltage.

A/D converter 28 including sample-hold circuit 29 obtains the difference between the reset voltage and the signal voltage in sample-hold circuit 29 and A/D-converts this difference, or independently A/D converts the reset voltage and the signal voltage and obtains the digital value of the difference between the reset voltage and the signal voltage.

In either case, A/D converter 28 outputs the difference (signal quantity) between the reset voltage and the signal voltage, so the amount of rise in voltage of output signal line 32 when the reset voltage of the floating diffusion is boosted is regarded as an offset and canceled. That is, only signal components of pixel signals can be precisely read (double correlated sampling process).

FIG. 5 illustrates an Example of a front side illumination type CMOS image sensor.

In this Example, semiconductor substrate 11 has p type and n-type photodiodes 12 are formed in p-type semiconductor substrate 11. Note that when n and p types are interchanged in FIG. 5, p-type photodiodes are formed in an n-type semiconductor substrate in this Example.

This Example shows n-type photodiodes because they allow the electron mobility to be higher than the hole mobility, thereby offering an advantage in a high-speed operation.

P-type semiconductor substrate 11 has a first surface (front surface) on the light incident side and a second surface (back surface) opposite to this light incident side. Photodiodes 12 are formed in p-type semiconductor substrate 11.

Functional layer 13 covers entire photodiodes 12 on the side of the first surface of p-type semiconductor substrate 11. In this Example, functional layer 13 covers both read transistors T and the entire first surface of p-type semiconductor substrate 11. Functional layer 13 has a function of transmitting light traveling from the exterior to the interior of p-type semiconductor substrate 11, and reflecting light traveling from the interior to the exterior of p-type semiconductor substrate 11, as described earlier.

Reflecting layer 14 covers the entire second surface of p-type semiconductor substrate 11, and has a function of reflecting light traveling from the interior to the exterior of p-type semiconductor substrate 11.

Also, light enters only photodiodes 12 via openings formed in light-shielding layer 15 on the side of the first surface. Interconnection layer 19 is arranged between light-shielding layer 15 and the first surface of p-type semiconductor substrate 11. Read transistors T transfer charges (signals) generated by photodiodes 12 to floating diffusions 17 under the control of the voltages applied to gates 16.

Element isolation layer 18 is formed in p-type semiconductor substrate 11. Element isolation layer 18 prevents charges generated in one pixel cell including photodiode 12 from leaking into other pixel cells adjacent to the pixel cell including photodiode 12.

In the front side illumination type CMOS image sensor, color filters 20 and microlenses 21 are arranged on the side of interconnection layer 19 (on the front side). Color filters 20 include, for example, red filters which transmit only red light, green filters which transmit only green light, and blue filters which transmit blue light.

In this Example, functional layer 13 covers at least photodiodes 12 which detect red light that is extracted by the red filters and is most poorly absorbed. Whether functional layer 13 is to be formed to cover only photodiodes 12 which detect red light or to cover all photodiodes 12 is desirably determined for each CMOS image sensor based on the performance of this CMOS image sensor.

Note that a CMOS image sensor is desirably formed in an SOI (Silicon on Insulator) substrate.

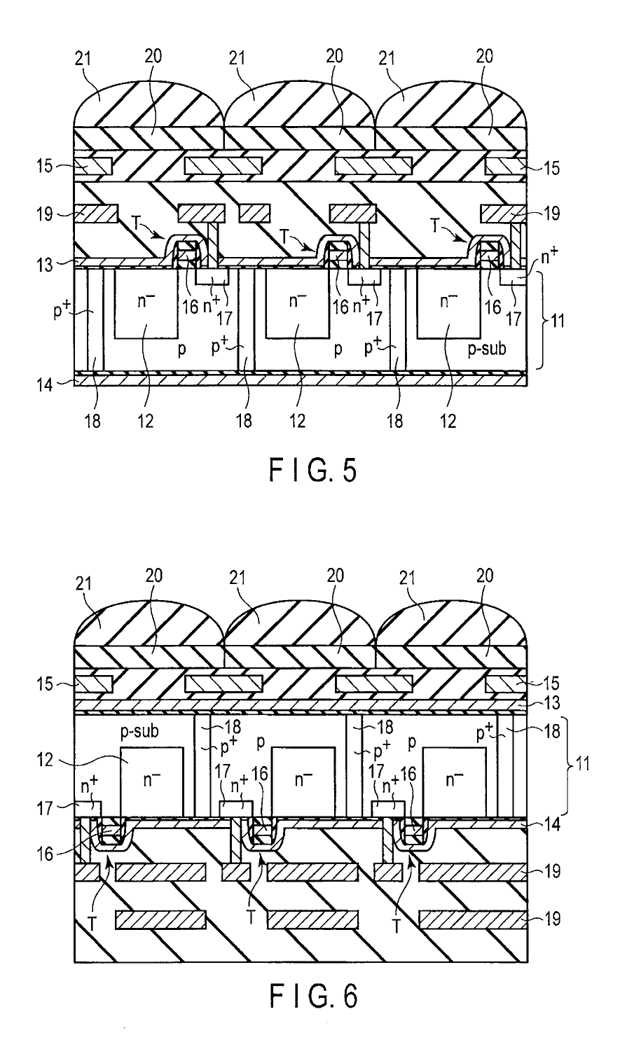

FIG. 6 illustrates an Example of a back side illumination type CMOS image sensor.

In this Example, semiconductor substrate 11 has p type and n-type photodiodes 12 are formed in p-type semiconductor substrate 11. Note that when n and p types are interchanged in FIG. 6, p-type photodiodes are formed in an n-type semiconductor substrate in this Example.

P-type semiconductor substrate 11 has a first surface (front surface) on the light incident side and a second surface (back surface) opposite to this light incident side. Photodiodes 12 are formed in p-type semiconductor substrate 11.

Functional layer 13 covers entire photodiodes 12 on the side of the first surface of p-type semiconductor substrate 11. In this Example, functional layer 13 covers the entire first surface of p-type semiconductor substrate 11. Functional layer 13 has a function of transmitting light traveling from the exterior to the interior of p-type semiconductor substrate 11, and reflecting light traveling from the interior to the exterior of p-type semiconductor substrate 11, as described earlier.

Reflecting layer 14 covers both read transistors T and the entire second surface of p-type semiconductor substrate 11. Reflecting layer 14 has a function of reflecting light traveling from the interior to the exterior of p-type semiconductor substrate 11.

Also, light enters only photodiodes 12 via openings formed in light-shielding layer 15 on the side of the first surface. Interconnection layers 19 are arranged on the side of the second surface of p-type semiconductor substrate 11. Read transistors T transfer charges (signals) generated by photodiodes 12 to floating diffusions 17 under the control of the voltages applied to gates 16.

Element isolation layer 18 is formed in p-type semiconductor substrate 11. Element isolation layer 18 prevents charges generated in one pixel cell including photodiode 12 from leaking into other pixel cells adjacent to the pixel cell including photodiode 12.

In the back side illumination type CMOS image sensor, color filters 20 and microlenses 21 are arranged on the back side opposite to that of interconnection layers 19. Color filters 20 include, for example, red filters which transmit only red light, green filters which transmit only green light, and blue filters which transmit blue light.

In this Example, functional layer 13 covers at least photodiodes 12 which detect red light that is extracted by the red filters and is most poorly absorbed. Whether functional layer 13 is to be formed to cover only photodiodes 12 which detect red light or to cover all photodiodes 12 is desirably determined for each CMOS image sensor based on the performance of this CMOS image sensor.

Note that a CMOS image sensor is desirably formed in an SOI substrate, as in the Example shown in FIG. 5. The Example shown in FIG. 6 assumes the use of an SOI substrate.

In this case, in a wafer process (a process of polishing the back surface), an insulating layer (silicon oxide layer) remains on the back side of p-type semiconductor substrate 11, so functional layer (for example, translucent layer) 13 can be directly formed on this insulating layer.

However, a CMOS image sensor may be formed in a bulk substrate.

In this case, in a wafer process, the back surface of the bulk substrate may or may not be polished. Also, an insulating layer is formed on the back surface of the bulk substrate, and functional layer 13 is formed on this insulating layer.

A method of manufacturing a CMOS image sensor according to the above-mentioned Examples will be described next.

The back side illumination type CMOS image sensor shown in FIG. 6 will be taken as a typical example herein. The front side illumination type CMOS image sensor shown in FIG. 5 can be easily fabricated by applying the following manufacturing method.

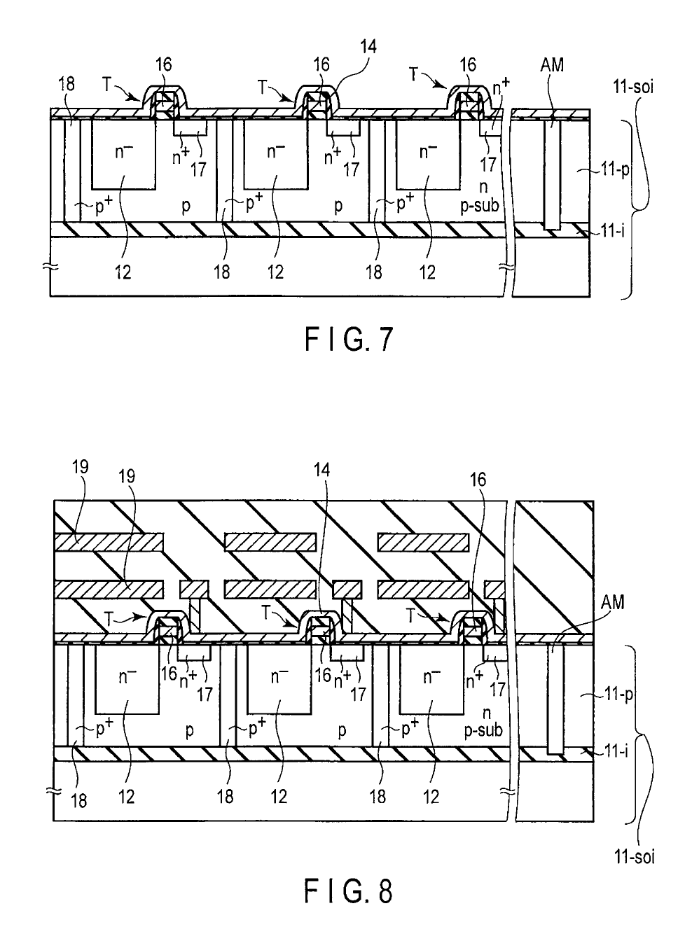

FIGS. 7, 8, 9, and 10 show a method of manufacturing the image sensor shown in FIG. 6. First, photodiodes 12, floating diffusions 17, and element isolation layer 18 are formed in p-type semiconductor layer 11-p on the front side of SOI substrate 11-soi using the ion implantation technique, as shown in FIG. 7.

Also, gates 16 of read transistors T are formed on p-type semiconductor layer 11-p.

Element isolation layer 18 extends from the front side of SOI substrate 11-soi to insulating layer (silicon oxide layer) 11-i in SOI substrate 11-soi.

Also, alignment mark AM is formed in p-type semiconductor layer 11-p on the front side of SOI substrate 11-soi. Alignment mark AM also extends from the front side of SOT substrate 11-soi to insulating layer (silicon oxide layer) 11-i in SOI substrate 11-soi. Note that a conductive layer such as TSV may be formed during formation of alignment mark AM.

Reflecting layer 14 is formed to cover the entire front side of SOI substrate 11-soi.

Interconnection layers 19 are formed on the front side of SOI substrate 11-soi, as shown in FIG. 8. In this case, no microlenses which guide light to photodiodes 12, for example, are arranged on the front side of SOI substrate 11-soi, so the freedom of design of interconnection layers 19 improves.

The back side of SOI substrate 11-soi is polished, as shown in FIG. 6. This polishing is done until insulating layer (silicon oxide layer) 11-i in SOI substrate 11-soi is exposed. Functional layer 13 is formed on insulating layer 11-i in SOI substrate 11-soi.

Also, light-shielding layer 15, color filters 20, and microlenses 21 are sequentially formed on functional layer 13.

Upon the above-mentioned process, the back side illumination type CMOS image sensor shown in FIG. 6 is completed.

Note that the following Modification is also possible.

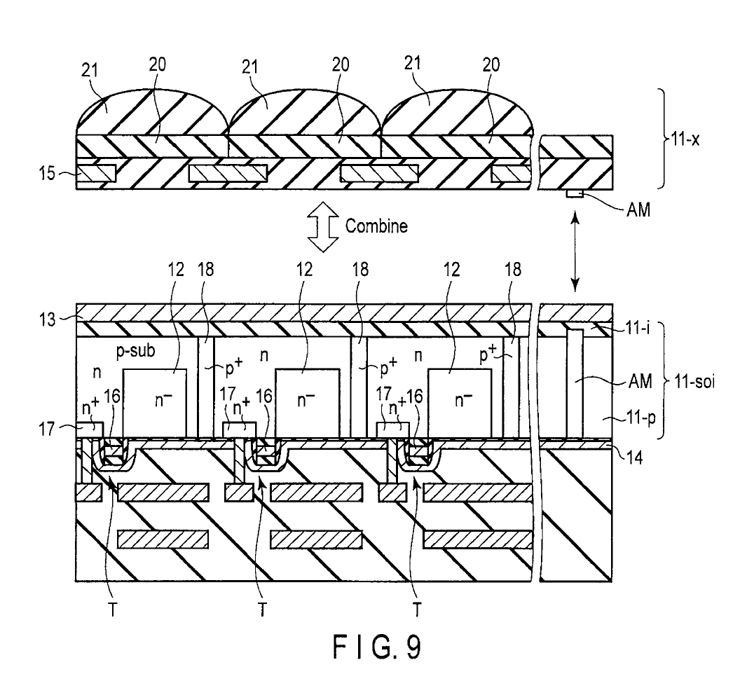

After the back side of SOI substrate 11-soi is polished in FIG. 8, functional layer 13 is formed on insulating layer 11-i in SOI substrate 11-soi, as shown in FIG. 9.

Structure 11-x which is formed separately from the above-mentioned process and includes color filters 20, microlenses 21, and light-shielding layer 15 is combined with the back surface (functional layer 13) of SOI substrate 11-soi.

At this time, SOI substrate 11-soi and structure 11-x are aligned with each other using alignment mark AM on the side of SOI substrate 11-soi and alignment mark AM on the side of structure 11-x.

The following Modification is moreover possible.

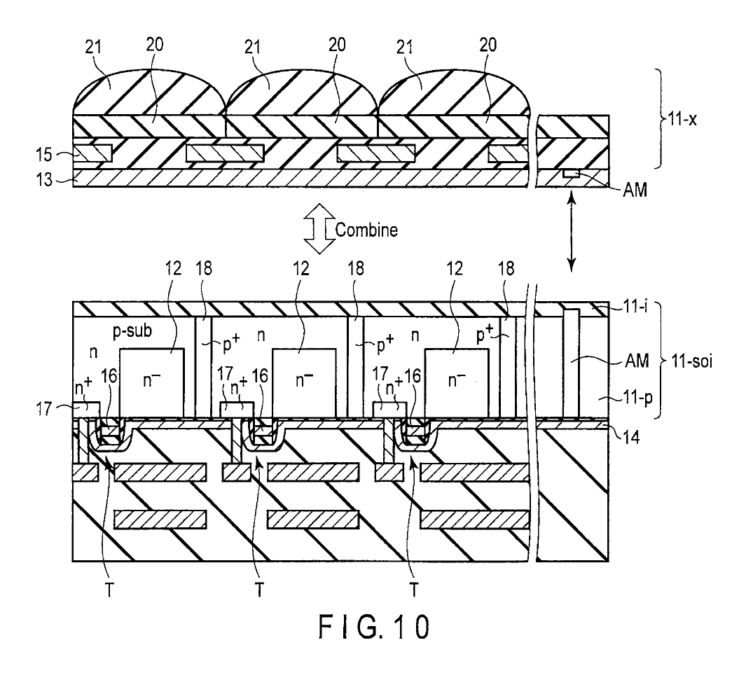

After the back side of SOI substrate 11-soi is polished in FIG. 8, structure 11-x including functional layer 13 is combined with SOI substrate 11-soi, as shown in FIG. 10.

### 3. CONCLUSION

According to the embodiment, it is possible to achieve vertical miniaturization of a photodiode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device comprising:
a semiconductor substrate having a first surface on a light incident side and a second surface on a side opposite to the light incident side;
a photodiode in the semiconductor substrate;
a functional layer which covers the entire photodiode on the side of the first surface of the semiconductor substrate, and has a function of transmitting the light traveling from an exterior to an interior of the semiconductor substrate, and reflecting the light traveling from the interior to the exterior of the semiconductor substrate; and
a reflecting layer which covers the entire second surface of the semiconductor substrate, and has a function of reflecting the light traveling from the interior to the exterior of the semiconductor substrate.

2. The device of claim 1, wherein the functional layer includes a translucent layer having a transmittance X (%) for the light, and a reflectance Y (%) for the light, that satisfy X+Y≦100.

3. The device of claim 1, wherein the functional layer covers the entire first surface of the semiconductor substrate.

4. The device of claim 1, wherein the light includes red light, and the functional layer covers only the photodiode which detects the red light.

5. The device of claim 1, further comprising an element isolation layer which extends from the side of the first surface to the side of the second surface in the semiconductor substrate.

6. The device of claim 1, further comprising a conductive layer which extends from the side of the first surface to the side of the second surface in the semiconductor substrate.

7. The device of claim 1, further comprising an alignment mark which extends from the side of the first surface to the side of the second surface in the semiconductor substrate.

8. A solid state imaging device comprising:
a semiconductor substrate having a first surface on a light incident side and a second surface on a side opposite to the light incident side;
a photodiode in the semiconductor substrate;
a read transistor which is arranged on the second surface of the semiconductor substrate, and transfers a charge generated by the photodiode;
a functional layer which covers the entire photodiode on the side of the first surface of the semiconductor substrate, and has a function of transmitting the light traveling from an exterior to an interior of the semiconductor substrate, and reflecting the light traveling from the interior to the exterior of the semiconductor substrate; and
a reflecting layer which covers the read transistor and the entire second surface of the semiconductor substrate, and has a function of reflecting the light traveling from the interior to the exterior of the semiconductor substrate.

9. The device of claim 8, wherein the functional layer includes a translucent layer having a transmittance X (%) for the light, and a reflectance Y (%) for the light, that satisfy X+Y≦100.

10. The device of claim 8, wherein the functional layer covers the entire first surface of the semiconductor substrate.

11. The device of claim 8, wherein the light includes red light, and the functional layer covers only the photodiode which detects the red light.

12. The device of claim 8, further comprising an element isolation layer which extends from the side of the first surface to the side of the second surface in the semiconductor substrate.

13. The device of claim 8, further comprising a conductive layer which extends from the side of the first surface to the side of the second surface in the semiconductor substrate.

14. The device of claim 8, further comprising an alignment mark which extends from the side of the first surface to the side of the second surface in the semiconductor substrate.

15. A solid state imaging device comprising:
a semiconductor substrate having a first surface on a light incident side and a second surface on a side opposite to the light incident side;
a photodiode in the semiconductor substrate;
a read transistor which is arranged on the first surface of the semiconductor substrate, and transfers a charge generated by the photodiode;
a functional layer which covers the read transistor and the entire photodiode on the side of the first surface of the semiconductor substrate, and has a function of transmitting the light traveling from an exterior to an interior of the semiconductor substrate, and reflecting the light traveling from the interior to the exterior of the semiconductor substrate; and
a reflecting layer which covers the entire second surface of the semiconductor substrate, and has a function of reflecting the light traveling from the interior to the exterior of the semiconductor substrate.

16. The device of claim 15, wherein the functional layer includes a translucent layer having a transmittance X (%) for the light, and a reflectance Y (%) for the light, that satisfy X+Y≦100.

17. The device of claim 15, wherein the functional layer covers the entire first surface of the semiconductor substrate.

18. The device of claim 15, wherein the light includes red light, and the functional layer covers only the photodiode which detects the red light.

19. The device of claim 15, further comprising one of an element isolation layer and a conductive layer, which extends from the side of the first surface to the side of the second surface in the semiconductor substrate.

20. The device of claim 15, further comprising an alignment mark which extends from the side of the first surface to the side of the second surface in the semiconductor substrate.
